(19) United States
(12) Patent Application Publication
(10) Pub. No.: US 2021/0261718 A1
(43) Pub. Date: Aug. 26, 2021

(54) HYBRID COPOLYMER COMPOSITION FOR PROTECTING FOLDABLE DISPLAYS

(71) Applicant: Tactus Technology, Inc., Fremont, CA (US)

(72) Inventors: Curtis Takagi, Fremont, CA (US); Matthew Han, Fremont, CA (US); Justin Virgili, Fremont, CA (US); Ryosuke Isobe, Fremont, CA (US); Brian Flamm, Fremont, CA (US); Leize Zhu, Newark, CA (US)

(21) Appl. No.: 17/316,614

(22) Filed: May 10, 2021

Related U.S. Application Data
(63) Continuation-in-part of application No. 16/723,797, filed on Dec. 20, 2019.
(60) Provisional application No. 62/806,808, filed on Feb. 16, 2019.
(60) Provisional application No. 62/783,067, filed on Dec. 20, 2018.

(51) Int. Cl. C08G 18/76; C08G 18/78; C08G 18/75; C08G 18/64; C08G 18/38; C08G 18/34; C08J 5/18

(52) U.S. Cl. CPC C08G 18/7628; C08G 18/7812; C08G 18/758; C08G 18/64; C08J 2375/02; C08G 18/348; C08J 5/18; C08J 2375/12; C08J 2375/06; C08G 18/3819

(57) ABSTRACT

A polymer composition includes: a first proportion of an aliphatic-diisocyanate terminated polyol; a second proportion of an aromatic diisocyanate; a third proportion of an aromatic diamine curative configured to extend a chain length of the aliphatic-diisocyanate-terminated polyol and the aromatic diisocyanate; a fourth proportion of a polyester polyol configured to polymerize with the aliphatic-diisocyanate-terminated polyol; and a fifth proportion of a high functionality dendrimer configured to crosslink polymer chains of the aliphatic-diisocyanate-terminated polyol. Further, the hybrid copolymer can be configured to form a protective film layer in a foldable electronic display, the foldable electronic display including: a cover layer arranged over the protective film layer; and an array of organic light-emitting diodes arranged beneath the protective film layer.

### CROSS-REFERENCE TO RELATED APPLICATIONS

This Application is a Continuation In Part application of U.S. patent application Ser. No. 16/723,797, filed on 20 Dec. 2019, which claims the benefit of U.S. Provisional Application No. 62/806,808, filed on 16 Feb. 2019, and U.S. Provisional Application No. 62/783,067, filed on 20 Dec. 2018, and is related to U.S. patent application Ser. No. 15/895,971, filed on 29 Apr. 2018, each of which are incorporated in their entireties by this reference.

### TECHNICAL FIELD

This invention relates generally to the field of hybrid copolymer chemistry and more specifically to a new and useful composition for protecting digital displays in the field of hybrid copolymer chemistry.

### BRIEF DESCRIPTION OF THE FIGURES

FIGS. 1A and 1B are schematic representations of the composition;

FIG. 2 is a schematic representation of the composition;

FIGS. 3A, 3B, 3C, 3D, 3E, 3F, and 3G are schematic representations of a foldable light-emitting diode display; and

FIG. 4 is a schematic representation of components of the composition;

FIG. 5 is a graphical representation of tan delta curves representative of examples of the composition.

### DESCRIPTION OF THE EMBODIMENTS

The following description of embodiments of the invention is not intended to limit the invention to these embodiments but rather to enable a person skilled in the art to make and use this invention. Variations, configurations, implementations, example implementations, and examples described herein are optional and are not exclusive to the variations, configurations, implementations, example implementations, and examples they describe. The invention described herein can include any and all permutations of these variations, configurations, implementations, example implementations, and examples.

### 1. Composition

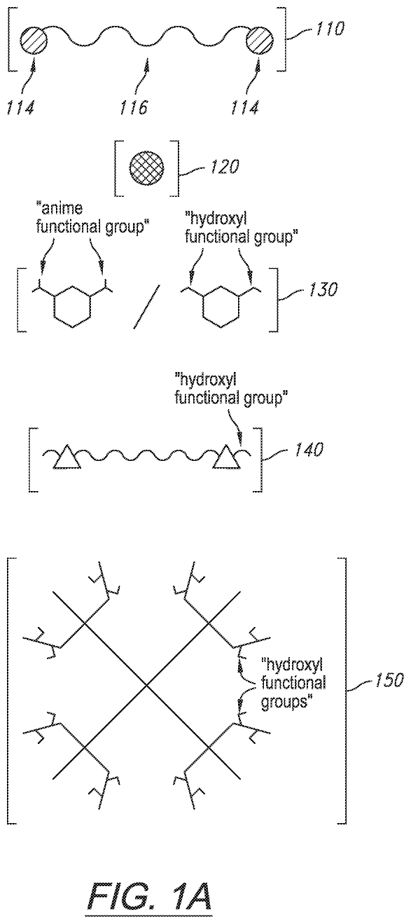

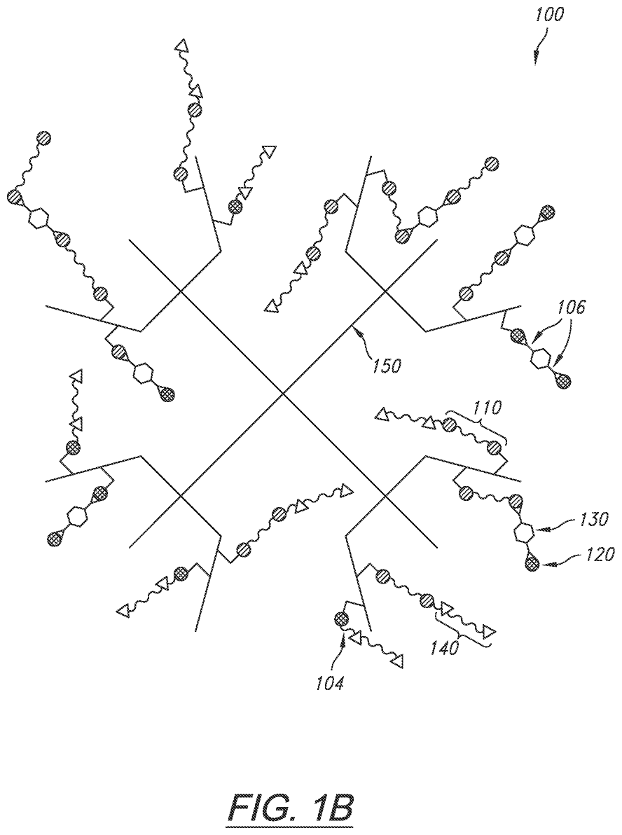

As shown in FIGS. 1A and 1B, a polymer composition 100 for protecting electronic displays includes: a first proportion of a polyisocyanate-terminated polyol 110; a second proportion of an additional polyisocyanate 120; a third proportion of a curative 130 configured to extend a chain length of the polyisocyanate-terminated polyol 110 and the additional polyisocyanate 120; a fourth proportion of a soft polymer chain 140 configured to polymerize with the polyisocyanate-terminated polyol 110 and the additional polyisocyanates 120; and a fifth proportion of a high functionality crosslinker 150 configured to crosslink the polyisocyanate-terminated polyol 110 and the additional polyisocyanate.

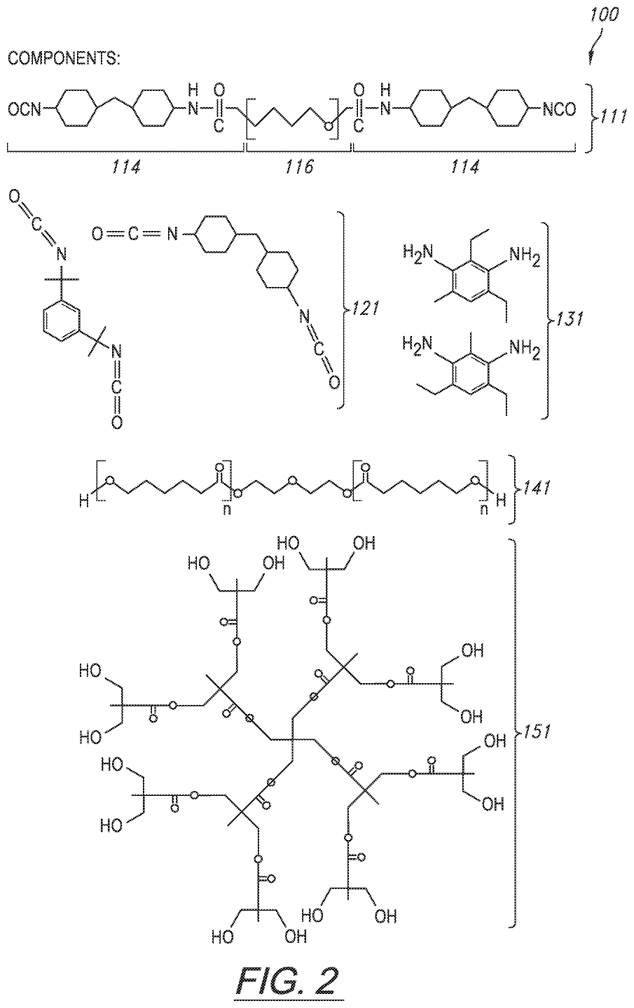

As shown in FIG. 2, one variation of the polymer composition 100 includes: a first proportion of an aliphatic-diisocyanate-terminated polyol 111; a second proportion of an additional diisocyanate 121; a third proportion of an aromatic diamine curative 131 configured to extend a chain length of the aliphatic-diisocyanate-terminated polyol 111 and the additional diisocyanate 121; a fourth proportion of a polyester polyol 141 configured to polymerize with the first proportion of aliphatic-diisocyanate-terminated polyol 111 and second proportion of additional diisocyanate 121; and a fifth proportion of a high functionality dendrimer 151 configured to crosslink polymer chains of the aliphatic-diisocyanate-terminated polyol.

One variation of the polymer composition 100 includes a molar ratio of a first number of urethane linkages 104 to a second number of urea linkages 106 between two-to-five and six-to-five. In this variation, the first number of urethane linkages 104: connect a first quantity of polyether polyol segments 112 to a second quantity of aliphatic diisocyanate terminations 114; connect a third quantity of polyester polyol segments 142 to the second quantity of the aliphatic diisocyanate terminations 114 and a fourth quantity of additional diisocyanates 120; and connect a fifth quantity of a high functionality crosslinker 150 to the second quantity of the aliphatic diisocyanate terminations 114 and the fourth quantity of additional diisocyanates 120. In this variation, the second number of urea linkages 106 connect a sixth quantity of an aromatic polyamine curative 132 to the second quantity of the aliphatic diisocyanate terminations 114 and the fourth quantity of additional diisocyanates 120.

In one variation, the polymer composition 100 includes: a first proportion of a polyisocyanate-terminated polyol 110; a second proportion of an additional polyisocyanate 120; a third proportion of a curative 130; a fourth proportion of a soft polymer chain 140 configured to interrupt crystallization of the first quantity of the polyisocyanate-terminated polyol below 50 degrees Celsius; and a high functionality crosslinker 150. In this variation, the polymer composition 100 exhibits: a first storage modulus between 300 MPa and 1400 MPa at −20 degrees Celsius; a second storage modulus between 10 MPa and 100 MPa at 85 degrees Celsius; a room temperature storage modulus between 50 MPa and 400 MPa at 20 degrees Celsius; and an elongation at break greater than 350%.

In one variation, the polymer composition 100 includes: a first proportion of polyol chains 116; a second proportion of polyisocyanates (e.g., polyisocyanate terminations 114 and additional polyisocyanates 120); a third proportion of a curative 130; a fourth proportion of a soft polymer chain 140; and a fifth proportion of a crosslinker 150. In this variation, the polymer composition 100 exhibits an impact resistance represented by a tan delta curve, the tan delta curve characterized by: a low-temperature tan delta between 0.05 and 0.25 at −20 degrees Celsius; a high-temperature tan delta between 0.05 and 0.30 at 85 degrees Celsius; and a maximum tan delta less than 0.4 at temperatures between −20 degrees Celsius and 85 degrees Celsius.

In one variation, the polymer composition 100 includes: a first amount of urethane linkages 104 connecting a first quantity of polyol segments 116 to a second quantity of a first subset of diisocyanates 114 and connecting a third quantity of a crosslinker 150 to a fourth quantity of a second subset of diisocyanates (e.g., diisocyanate terminations 114 and/or additional diisocyanates 120); and a second amount of urea linkages 106 connecting a fifth quantity of a curative 130 to a sixth quantity of a third subset of diisocyanates (e.g., diisocyanate terminations 114 and/or additional diisocyanates 120). In this variation, the polymer composition 100 exhibits: an impact resistance characterized by a tan delta between 0.05 and 0.4 at temperatures between −20 degrees Celsius and 85 degrees Celsius; and a room temperature storage modulus between 50 MPa and 400 MPa at 20 degrees Celsius.

In one variation, the polymer composition 100 includes: a first amount of urethane linkages 104 connecting a first quantity of polyol segments 116 to a second quantity of a first subset of diisocyanates 114 and connecting a third quantity of a crosslinker 150 to a fourth quantity of a second subset of diisocyanates (e.g., diisocyanate terminations 114 and/or additional diisocyanates 120); and a second amount of urea linkages 106 connecting a fifth quantity of a curative 130 to a sixth quantity of a third subset of diisocyanates (e.g., diisocyanate terminations 114 and/or additional diisocyanates 120). In this variation, the polymer composition 100 exhibits: a set of optical properties including a haze value less than 1.3 percent and a yellowness index less than 1.1; and a surface roughness between 5 nanometers and 40 nanometers.

In one variation, the polymer composition 100 includes a first amount of urethane linkages 104. The polymer composition 100 exhibits a tan delta curve characterized by: a low-temperature tan delta between 0.05 and 0.25 at −20 degrees Celsius; a high-temperature tan delta between 0.05 and 0.30 at 85 degrees Celsius; and a maximum tan delta less than 0.4 at temperatures between −20 degrees Celsius and 85 degrees Celsius. Further, the polymer composition 100 exhibits: a surface roughness characterized by an arithmetic mean deviation between 5 nanometers and 40 nanometers; a haze value less than 1.3 percent; and a yellowness index less than 1.1. Further, in this variation, a film including the polymer composition 100 exhibits a bend height less than 0.5 millimeters after subjecting the film to a bend test.

### 2. Applications

Generally, as shown in FIGS. 1A and 1B, a polymer composition 100 (e.g., a hybrid urea-urethane copolymer composition) includes a polyisocyanate-terminated polyol 110, additional polyisocyanates 120; a curative 130/chain length extender, a soft polymer chain 140, and a high functionality crosslinker 150 such that, when the polymer composition 100 is cured in a continuous roll-to-roll process, the polymer composition 100 exhibits optical clarity (e.g., an optical transmission of greater than 90% and/or voids with a characteristic size less than 100 nanometers); impact resistance (e.g., an impact resistance characterized by a tan delta between 0.05 and 0.4 at temperatures between −20 degrees Celsius and 85 degrees Celsius); mechanical stability between −20° C. and 85° C. (e.g., a storage modulus between 300 and 1400 MPa at −20° C. and a storage modulus between 10 and 100 MPa at 85° C.); flexibility/foldability (e.g., a repeatable 2-millimeter bend radius), and UV stability. Furthermore, in prepolymer form, the polymer composition 100 is workable via a roll-to-roll manufacturing process, such as described in U.S. application Ser. No. 15/895,971. When manufactured as a thin film, the polymer composition 100 can function as a protective layer 102 in a foldable electronic display (or touchscreen), thereby protecting a display layer in the foldable electronic display from damage due to impact, scratching, or abrasion while maintaining its optical and mechanical properties after repetitive flexion (e.g., folding) of the display. Additionally and/or alternatively, the polymer composition 100 can function as a sponge film 103 configured to provide impact resistance to a mechanical housing of a foldable electronic display. Thus, without sacrificing optical properties, the polymer composition 100 exhibits improved impact resistance and durability to repetitive flexion of foldable electronic displays as compared to other foldable display technology. For example, a foldable electronic display including a protective layer 102 manufactured from the polymer composition 100 may exhibit minimal optical and mechanical changes when folded with a 2-millimeter bend radius 200,000 times.

The polymer composition 100 can exhibit the abovementioned properties by effectively combining: qualities of aliphatic isocyanate-polyol polymers, such as UV stability and slower reaction rates during polymerization, qualities of aromatic isocyanate-polyol polymers, such as high elongation at break (e.g., greater than 350 percent), and qualities of polyureas, such as flexibility and durability. Furthermore, the polymer composition 100 includes: a curative 130 that yields a relatively long polymer chain length in the polymer composition 100; and a high functionality crosslinker 150 that yields a high bulk crosslink density in the polymer composition 100. More specifically, the curative 130 is configured to extend a chain length of the polyisocyanate-terminated polyol 110 and the additional polyisocyanates 120 via urea linkages 106 and the high functionality crosslinker 150 is configured to crosslink the polyisocyanate-terminated polyol 110 and additional polyisocyanates in a radially-integrated pattern via urethane linkages 104, thereby providing greater storage modulus at higher temperatures while maintaining flexibility at lower temperatures. The polymer composition 100 also includes the soft polymer chain 140 which is configured to polymerize with the polyisocyanate terminations 114 of the polyisocyanate-terminated polyol 110 and the additional polyisocyanates 120 to control crystallization of the polyisocyanate-terminated polyol 110 at low temperatures, thereby providing lower storage modulus at low temperatures when compared with typical polyurethane compositions.

In one implementation, as shown in FIG. 2, the polymer composition 100 includes an aliphatic-diisocyanate-terminated polyol 111 as the polyisocyanate-terminated polyol 110; additional diisocyanates 121 as the additional polyisocyanates 120; an aromatic diamine curative 131 as the curative 130; a polyester polyol 141 as the soft polymer chain 140; and a high functionality dendrimer 151 as the high functionality crosslinker 150.

The polymer composition 100 can include a catalyst, which aids in improving processing times. The catalyst can include any polyurethane catalyst configured to initiate polyurethane and/or polyurea polymerization that does not present environmental health and safety concerns during the manufacturing process or in the completed product (e.g., when included in a light-emitting diode display). Additionally, the polymer composition 100 can include additives, including but not limited to surfactants, de-foamers, self-leveling agents, and/or wetting agents, which can reduce the surface tension of the prepolymer mixture and thereby improve the surface quality of a protective film manufactured from the polymer composition 100.

Furthermore, the prepolymer mixture of the polymer composition 100 is soluble in aprotic, polar organic solvents, such as methyl ethyl ketone (hereinafter “MEK”), which can substantially evaporate during the roll-to-roll manufacturing process while reducing the viscosity of the prepolymer mixture.

### 3. Foldable Display

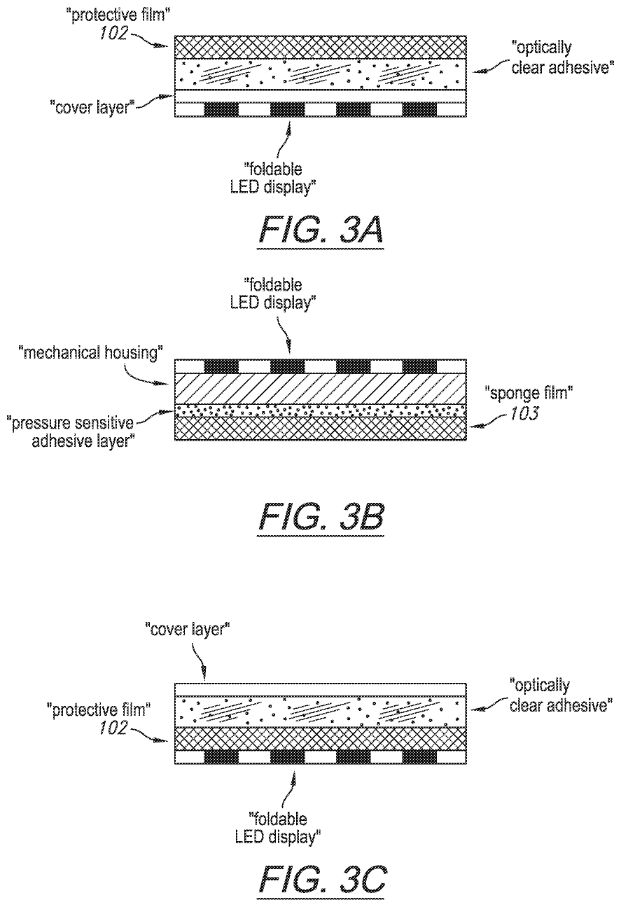

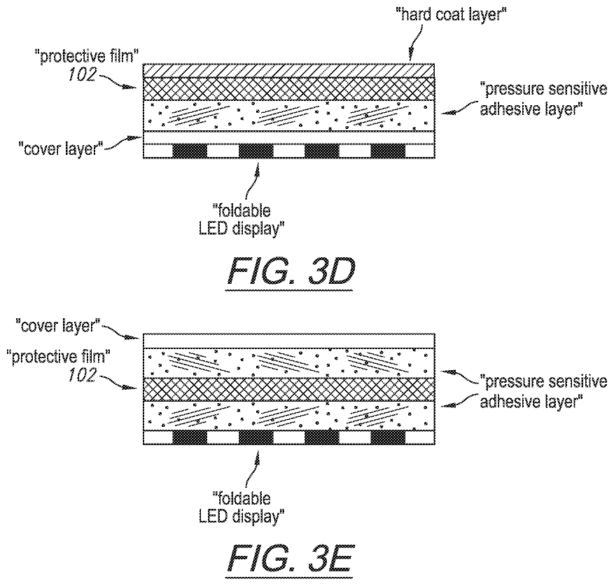

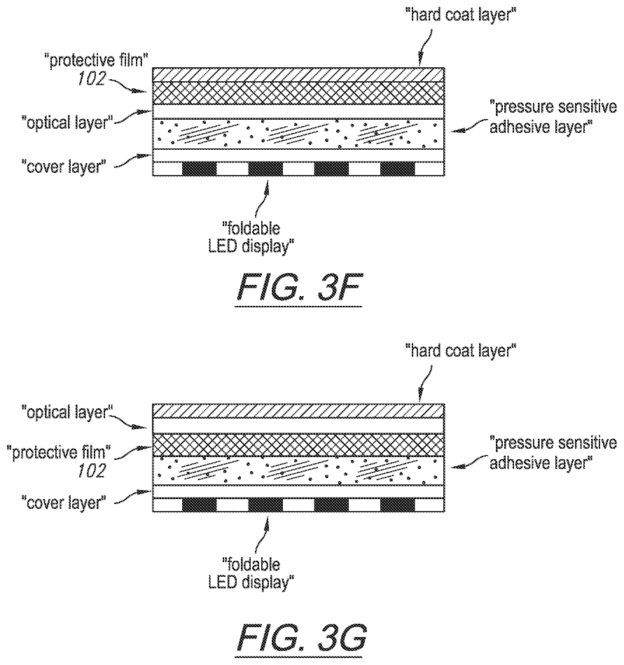

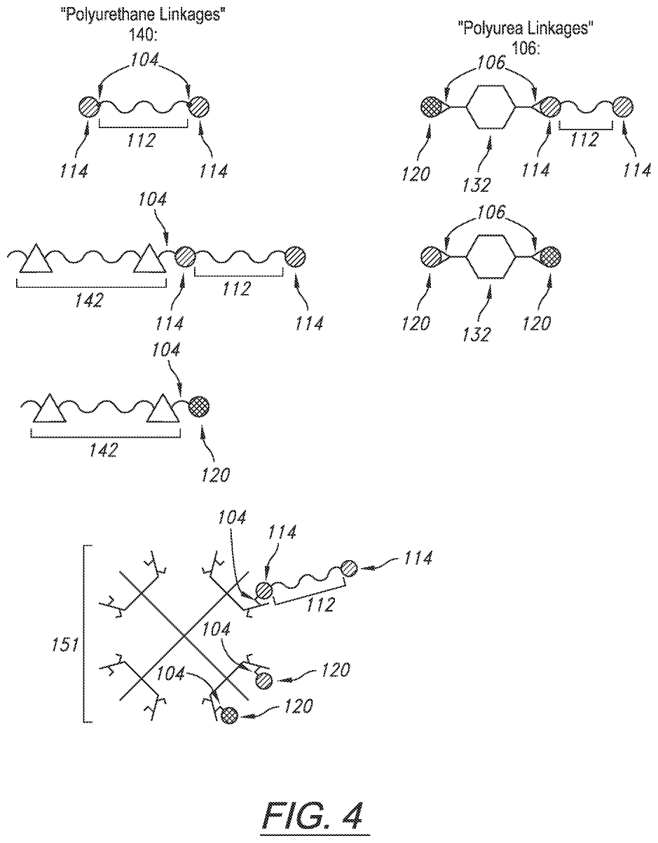

In one implementation, as shown in FIGS. 3A-3G, the polymer composition 100 can be configured to form a protective film layer 102 in a foldable electronic display. As shown in FIG. 3A, the polymer composition 100 can be configured to form a protective film layer 102 for a foldable electronic display, the foldable electronic display including: a foldable light-emitting diode (hereinafter “LED”) display (e.g., an array of organic light emitting diodes); and a cover layer. The protective film layer 102 includes: a first proportion of the polyisocyanate-terminated polyol 110; the second proportion of additional polyisocyanates 120; a third proportion of the curative 130; a fourth proportion of the soft polymer chain 140; and the fifth proportion of a high functionality crosslinker.

In one implementation, the foldable electronic display includes a protective film layer 102 arranged above the cover layer and secured via an pressure sensitive adhesive as shown in FIG. 3A. In another implementation, the foldable electronic display includes a protective film layer 102 arranged between the cover layer and the foldable electronic display as shown in FIG. 3C. In yet another implementation, the foldable electronic display includes a first protective film layer 102 arranged above the cover layer and a second protective film layer 102 arranged beneath the cover layer both secured via layers of pressure sensitive adhesive. Additionally or alternatively, the foldable electronic display can include pressure sensitive adhesive to adhere the cover layer to the protective film or the protective film layer 102 to the foldable electronic display.

In one implementation, as shown in FIGS. 3D-3F, the polymer composition 100 can be configured to form a protective film layer 102 integrated into a laminated film in a foldable electronic display. In this implementation, the laminated film can include: a hard coat layer; an optical layer; the protective film layer 102; and/or an pressure sensitive adhesive layer (e.g., an optically clear adhesive layer). The laminated film can include any combination of these layers and can also be configured to include additional layers. For example, the laminated film can include the protective film layer 102 and the pressure sensitive adhesive layer. In another example, the laminated film can include the protective film layer 102 and the hard coat layer. In yet another example, the laminated film can include the hard coat layer, the protective film layer 102, the optical layer, and the pressure sensitive adhesive layer (e.g., an optically clear adhesive layer).

In this implementation, the protective film layer, including the polymer composition 100, can exhibit a thickness between 5 micrometers and 120 micrometers.

In this implementation, the laminated film can include the hard coat layer including any combination of resins, inorganic materials, and/or organic materials. For example, the hard coat layer can include: a resin such as a (meth)acryl resin, an epoxy resin, a silicone resin, an oxetane resin, a urethane resin, an urethane (meth)acrylate resin, and/or any combination of these resins; an inorganic material such as silica, alumina, zirconia, and/or any combination of these inorganic materials; and/or an organic material such polysilsesquioxane or a mixture thereof. Further, the hard coat layer can exhibit: a water contact angle of the hard coat layer surface greater than or equal to 110 degrees; a pencil hardness tested at 250 grams load greater than or equal to H; and a thickness between 2 micrometers and 30 micrometers.

Additionally, in this implementation, the laminated film can include an optical layer including a polymeric or glass substrate. In one example, the optical layer can include a polymer substrate such as polyethylene terephthalate, polyethylene naphthalate, colorless polyimide, cyclic olefin copolymer, polysulfide, polycarbonate, and/or acrylic. In another example, the optical layer can include a foldable glass substrate such as ultra-thin glass. Further, the optical layer can exhibit a thickness between 5 micrometers and 100 micrometers.

Additionally, in this implementation, the laminated film can include the pressure sensitive adhesive film layer. In one example, the pressure sensitive adhesive layer can include a silicone including resin, acryl based resin, and/or urethane based resin or copolymer thereof based resin. The pressure sensitive adhesive layer can exhibit: a room temperature storage modulus between 10 kPa and 250 kPa at 25 degrees Celsius; a storage modulus between 10 kPa and 500 kPa at temperatures between −20 degrees Celsius and 85 degrees Celsius; a maximum tan delta equivalent or less than 0.40; and a thickness between 5 micrometers and 50 micrometers.

In one example, as shown in FIG. 3F, the laminated film can include: the hard coat layer; the protective film layer 102 arranged beneath the hard coat layer and above the optical layer; the optical layer arranged beneath the protective film layer 102 and above the pressure sensitive adhesive layer; and the pressure sensitive adhesive layer arranged below the optical layer. In another example, as shown in FIG. 3G, the laminated film can include: the hard coat layer; the optical layer arranged beneath the hard coat layer and above the protective film layer 102; the protective film layer 102 arranged beneath the optical layer and above the pressure sensitive adhesive layer; and the pressure sensitive adhesive layer arranged below the protective film layer 102.

In one implementation, in which the polymer composition 100 is configured to form the protective film layer 102, the polymer composition 100 can exhibit a release liner adhesion between 0.05 Newtons-per-25-millimeters and 1.0 Newtons-per-25-millimeters. In another implementation, in which the polymer composition 100 is configured to form the protective film layer 102, the polymer composition 100 can exhibit a release liner adhesion between 0.05 Newtons-per-25-millimeters and 0.5 Newtons-per-25-millimeters.

The polymer composition 100 can be manufactured via a roll-to-roll manufacturing process to form a protective film 102 configured for insertion in a foldable electronic display stack. For example, the polymer composition 100 can form a protective film exhibiting: a thickness between 5 micrometers and 120 micrometers; and a flexibility characterized by bending the film layer around a two-millimeter mandrel, unfolding the film, and observing no damage or change in the protective film 102 after repeating this process over 200,000 times. Additionally, the protective film 102 exhibits desirable optical qualities including: transmission greater than ninety percent; haze less than one percent; and clarity greater than ninety percent.

In another implementation, as shown in FIG. 3B, the polymer composition 100 can be manufactured to form a sponge layer 103 in a foldable electronic display, the foldable electronic display including: a foldable light-emitting diode (hereinafter “LED”) display; and a mechanical housing arranged below the LED display and above the sponge layer 103. Additionally or alternatively, the foldable electronic display can include a pressure sensitive adhesive layer; For example, the polymer composition 100 can form the sponge layer 103 exhibiting: a thickness between 5 micrometers and 120 micrometers; and an elongation at break greater than 350 percent.

However, a foldable electronic display including the protective film layer 102 or the sponge layer 103 can include additional layers or components not described above or shown in FIGS. 3A-3G. Alternatively, a foldable electronic display including the protective film layer 102 or the sponge layer 103 can include fewer layers or components shown in FIGS. 3A-3G.

### 4. Polymer Properties

The polymerized form of the polymer composition 100 exhibits qualities that are favorable for use as a protective film (i.e., protective layer 102) within an electronic display. More specifically, the polymerized form of the polymer composition 100 exhibits qualities favorable for insertion as a protective film layer 102 within a foldable electronic display, such as an LED display (e.g., an organic LED display). In particular, the polymer composition 100 can be configured to exhibit qualities such that—when inserted as a protective film layer 102 within a foldable electronic display—the protective film layer 102 exhibits increased impact resistance, increased bending performance, and relatively high reliability (e.g., under extreme environmental conditions). Therefore, the polymer form of the polymer composition 100 exhibits: higher storage modulus at high temperatures and lower storage modulus at lower temperatures than a typical polyurethane-based or poly(urea-urethane)-based elastomer, thereby enabling a thin film of the polymer composition 100 (e.g., with a thickness between 5 and 120 micrometers) to protect the electronic display from impact, scratching, and abrasion over a wide range of temperatures (−20° C. to 85° C.); lower loss factor (or “tan delta”) over a wide range of temperatures, thereby enabling a thin film of the polymer composition 100 to quickly absorb force with high elasticity; high flexibility, thereby enabling the polymer composition 100 to repeatedly bend around a small radius without noticeable deformation or degradation; optical clarity, which enables a user to view an image rendered on the electronic display without significant optical aberrations; and UV stability (e.g., UV resistance), thereby preserving perceived color of images rendered by the underlying electronic display.

### 4.1 Storage Modulus

The polymerized polymer composition 100 can exhibit a storage modulus between 50 MPa and 400 MPa at 20° C. (as measured via dynamic mechanical analysis testing using a tension clamp from −70° C. and ° C. with a 2° C./min warming rate, an oscillation rate of 1 Hz, and a force control of 0.1 N), depending on factors (further discussed below) including: the functionality and weight percentage of the curative 130 included in the polymer composition 100; the molecular weight and type of the polyol in the polyisocyanate terminated polyol 110; the weight percentage and chemistry of the additional polyisocyanates 120; the molecular weight and weight percentage of the soft polymer chain 140; and the weight percentage and degree of functionality of the high functionality crosslinker 150.

The polymerized polymer composition 100 can exhibit relatively low variation in storage modulus over its operating temperature range. For example, the polymer composition 100 can exhibit a storage modulus between 300 MPa and 1400 MPa at −20° C., a storage modulus between 50 and 400 MPa at 20° C., and a storage modulus between 10 MPa and 100 MPa at 85° C. Furthermore, the polymerized polymer composition 100 can exhibit a relatively high glass transition temperature, such as between 40° C. and 75° C. (as measured via dynamic mechanical analysis testing using a tension clamp from −70° C. to 150° C. with a 2° C./min heating rate, an oscillation rate of 1 Hz, and a force control of 0.1 N). The low variation in storage modulus and high glass transition temperature of the polymer composition 100 results in part from the hybrid nature of the copolymer, wherein hard polymer segments include the isocyanate terminations 114 of the polyisocyanate-terminated polyol 110, the additional polyisocyanates 120, and the curative 130 chain extender; and wherein soft polymer segments include the polyol segments of the polyisocyanate-terminated polyol no and the soft polymer segment. Generally, the hard polymer segments maintain the rigidity of the polymer composition 100 at high temperatures while the soft polymer segments prevent excess hardening of the polymer composition 100 at low temperatures. Thus, temperature-dependent storage modulus characteristics of the polymer composition 100 may be tuned by adjusting the weight percentage of the hard polymer segment components in relation to the weight percentage of the soft polymer segment components.

The polymer composition 100 can be characterized by a modulus ratio (i.e., a change in the storage modulus of the polymer composition 100 defined as the final storage modulus divided by the initial storage modulus expressed as a percentage and subtracting 100 percent) responsive to exposure to temperatures within different temperatures ranges for a set duration. In one implementation, the polymer composition 100 can: exhibit a first modulus ratio between two percent and twenty percent after 5 weeks of storage at a low holding temperature of −10 degrees Celsius; a second modulus ratio between two percent and twenty percent after 5 weeks of storage at a moderate holding temperature of 23 degrees Celsius; and a third modulus ratio between two percent and twenty percent after 5 weeks at an upper holding temperature of 50 degrees Celsius.

For example, the first modulus ratio of the polymer composition 100 can be characterized by: at a first time prior to a first test period, measuring a first initial storage modulus of the polymer composition 100; during the first test period, storing the polymer composition 100 at −10 degrees Celsius for a duration of 5 weeks; at a second time succeeding the first test period, measuring a first final storage modulus of the polymer composition 100; and, calculating the first modulus ratio of the polymer composition 100 as a ratio of the first final storage modulus to the first initial storage modulus. The second modulus ratio of the polymer composition 100 can be characterized by: at a first time prior to a second test period, measuring a second initial storage modulus of the polymer composition 100; during the second test period, storing the polymer composition 100 at 23 degrees Celsius for a duration of 5 weeks; at a second time succeeding the second test period, measuring a second final storage modulus of the polymer composition 100; and, calculating the second modulus ratio of the polymer composition 100 as a ratio of the second final storage modulus to the second initial storage modulus. The third modulus ratio of the polymer composition 100 can be characterized by: at a first time prior to a third test period, measuring a third initial storage modulus of the polymer composition 100; during the third test period, storing the polymer composition 100 at 50 degrees Celsius for a duration of 5 weeks; at a second time succeeding the third test period, measuring a third final storage modulus of the polymer composition 100; and, calculating the third modulus ratio of the polymer composition 100 as a ratio of the third final storage modulus to the third initial storage modulus.

### 4.2 Tan Delta

The polymer composition 100 can exhibit an impact resistance represented by a tan delta (or dissipation or loss factor) between 0.05 and 0.40 at temperatures between −20 degrees Celsius and 85 degrees Celsius. The polymer composition 100 can therefore exhibit relatively low variation in tan delta over a wide range of temperature. By maintaining this relatively low tan delta (e.g., less than 0.40) across this wide range of temperatures, the polymer composition 100 can exhibit increased impact resistance, increased folding resistance, and increased elastic recovery across this wide range of temperatures.

In one implementation, the polymer composition 100 can exhibit: a low-temperature tan delta between 0.05 and 0.25 at −20 degrees Celsius; a high-temperature tan delta between 0.05 and 0.30 at 85 degrees Celsius; and a maximum tan delta less than 0.40 at temperatures between −20 degrees Celsius and 85 degrees Celsius. In one example, the polymer composition 100 exhibits: a low-temperature tan delta between 0.05 and 0.15 at −20 degrees Celsius; a high-temperature tan delta between 0.10 and 0.25 at 85 degrees Celsius; and a maximum tan delta less than 0.30 at approximately (e.g., within 3 degrees Celsius) 24 degrees Celsius.

In this implementation, as described above, the polymer composition 100 can exhibit a maximum tan delta less than 0.40 at temperatures between −20 degrees Celsius and 85 degrees Celsius. Examples of the maximum tan delta (or “Peak Tan Delta”) and corresponding temperatures (or “Tan Delta Peak Temp”) for the polymer composition 100 are listed below in Table 1.

TABLE 1

| | Tan Delta | Peak |
|---|---|---|
| | Peak Temp | Tan |
| Example | (° C.) | Delta |
| Example #1 | 24, 108 | 0.18, 0.16 |
| Example #2 | 60 | 0.22 |
| Example #3 | 60 | 0.20 |
| Example #4 | 52 | 0.22 |
| Example #5 | 24 | 0.20 |
| Example #6 | 12 | 0.21 |
| Example #7 | 12 | 0.20 |

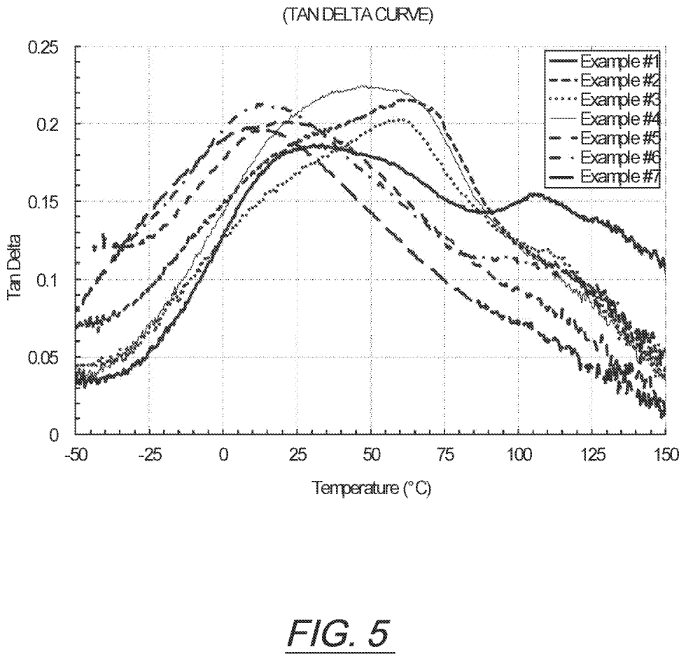

Further, as shown in FIG. 5, the impact resistance of the polymer composition 100 can be represented by a tan delta curve. In particular, this tan delta curve represents changes in the tan delta of the polymer composition 100 as a function of temperature.

More specifically, FIG. 5 depicts seven variations of the tan delta curve, each of these variations representative of an example of the polymer composition 100 included in Table 1.

In each of the seven examples of the polymer composition 100 included in Table 1, the polymer composition 100 includes: a first proportion of a polyisocyanate-terminated polyol 110; a second proportion of additional polyisocyanates 120; a third proportion of a curative 130/chain length extender; a fourth proportion of a soft polymer chain 140; a fifth proportion of a high functionality crosslinker 150; a sixth proportion of a catalyst; and a seventh proportion of a surface additive.

In particular, the polymer composition 100 of Example #1 includes a first proportion of a polyether polyisocyanate-terminated polyol 110 exhibiting an average molecular weight between 650 g/mol and 2600 g/mol as the first proportion of the polyisocyanate-terminated polyol 110. The polymer composition 100 of Example #1 further includes an eighth proportion of a UV stabilizer.

The polymer composition 100 of Example #2 includes a first proportion of a polycaprolactone polyisocyanate-terminated polyol no exhibiting an average molecular weight between 500 and 2600 g/mol as the polyisocyanate-terminated polyol 110.

Similarly, the polymer composition 100 of Example #3 includes the first proportion of a polycaprolactone polyisocyanate-terminated polyol no as the polyisocyanate-terminated polyol 110. However, the polymer composition 100 of Example #3 further includes an eighth proportion of a UV stabilizer.

The polymer composition 100 of Example #4 includes the first proportion of polyisocyanate-terminated polyol 110 including a 3 to 1 (w/w) ratio of: a polycaprolactone polyisocyanate-terminated polyol exhibiting an average molecular weight between 500 g/mol and 2600 g/mol; and a polyether polyisocyanate-terminated polyol exhibiting an average molecular weight between 650 g/mol and 2600 g/mol.

The polymer composition 100 of Example #5 includes the first proportion of polyisocyanate-terminated polyol 110 including a 3 to 2 (w/w) ratio of: a polyether polyisocyanate-terminated polyol exhibiting an average molecular weight between 650 g/mol and 1000 g/mol; and a polyether polyisocyanate-terminated polyol exhibiting an average molecular weight between 1000 g/mol and 2600 g/mol.

The polymer composition 100 of Example #6 includes the first proportion of polyisocyanate-terminated polyol 110 including a 1 to 1 (w/w) ratio of: a polyether polyisocyanate-terminated polyol exhibiting an average molecular weight between 650 g/mol and 1000 g/mol; and a polyether polyisocyanate-terminated polyol exhibiting an average molecular weight between 1000 g/mol and 2600 g/mol.

The polymer composition 100 of Example #7 includes a first proportion of the polyisocyanate-terminated polyol 110 including a 2 to 3 (w/w) ratio of a polyether polyisocyanate-terminated polyol exhibiting an average molecular weight between 650 g/mol and 1000 g/mol; and a polyether polyisocyanate-terminated polyol exhibiting an average molecular weight between 1000 g/mol and 2600 g/mol.

In one implementation, the impact resistance of the polymer composition 100 can be represented by a tan delta curve characterized by a full width at half maximum between 70 degrees Celsius and 180 degrees Celsius. In this implementation, the tan delta curve can include: a low-temperature tan delta between 0.05 and 0.25 at −20 degrees Celsius; a high-temperature tan delta between 0.05 and 0.30 at 85 degrees Celsius; and a maximum tan delta less than 0.40 at temperatures between −20 degrees Celsius and 85 degrees Celsius. As shown in FIG. 5, the polymer composition 100 can thus exhibit an impact resistance characterized by a tan delta curve exhibiting a relatively broad, wide peak, rather than a steep, narrow peak. Therefore, by maintaining this relatively high full width at half maximum (e.g., between 70 degrees Celsius and 180 degrees Celsius), the polymer composition 100 can exhibit increased impact resistance and high elasticity across a large temperature range.

### 4.3 Flexibility

The polymerized polymer composition 100 can also exhibit high static and dynamic flexibility. The static flexibility of the polymerized hybrid copolymer can be characterized by bending a thin film of the polymer composition 100 around a 2-millimeter radius mandrel for four hours at 25° C. without the thin film of the polymer composition 100 exhibiting permanent deformation or degradation of optical or mechanical properties. The dynamic flexibility of the polymerized polymer composition 100 can be characterized by repeatedly bending the thin film of the polymer composition 100 around a 2-millimeter radius mandrel at a frequency of 1 Hz for 200,000 cycles without the thin film of the polymer composition 100 exhibiting permanent deformation or degradation of optical or mechanical properties.

In one implementation, a film formed of the polymer composition 100 can exhibit a bend height less than 0.50 millimeters when subjected to a bend test. In this implementation, a bend test can include a series of bend test cycles (e.g., 1,000 bend test cycles, 100,000 bend test cycles, 200,000 bend test cycles), each bend test cycle including bending and unbending the film, formed of the polymer composition 100, around a 1-millimeter radius surface (e.g., a 1-millimeter radius mandrel). After completion of the bend test, the bend height can be measured by laying the film on a flat surface—such that a concave surface of the film faces the flat surface—and measuring a perpendicular distance between the flat surface and a center of the film. In one example, the film can exhibit a bend less than 0.20 millimeters when subjected to a bend test including at least 1,000 bend test cycles.

Additionally and/or alternatively, in one implementation, a film formed of the polymer composition 100 can be visually inspected at the completion of testing for evidence of cracking, permanent creasing, or changes in haze.

The flexibility and/or foldability of the polymer composition 100 may be tuned, in part, by adjusting the proportions of the curative 130 and the high functionality crosslinker 150, which affects the bulk crosslinking density of the polymer composition 100. Furthermore, the flexibility and/or foldability of the polymer composition 100 can be modified by adjusting the molecular weight and type of the polyol in the polyisocyanate terminated polyol 110; the weight percentage and chemistry of the additional polyisocyantes 120; the molecular weight type and weight percentage of the soft polymer chain 140; and the weight percentage of the high functionality crosslinker 150. In one implementation, the polymer composition 100 can exhibit a bulk density between 1.1 and 1.4 g/cm³ and a void fraction between three and twenty percent, thereby enabling enhanced impact performance of the polymer composition 100.

### 4.4 Optical Properties

Furthermore, the polymerized hybrid copolymer can exhibit high optical clarity. For example, the polymerized polymer composition 100 can exhibit optical transmission greater than 90%, haze less than 1.3%, clarity greater than 90%; and CIE 1976 Color Scale values of L* greater than 90, a* greater than −1.0 and less than 1.0, and b* greater than −1.0 and less the 1.0 (e.g., measured according to ASTM D6290 with a 10-degree observer angle and Illuminant D65); and a yellowness index equivalent to or less than 1.1. The optical properties are enabled by the amorphous structure of the soft polymer segment of the polymer composition 100 and control over the degree of crystallinity and crystallite size of the hard segment. However, the polymerized polymer composition 100 may exhibit properties different than those described above when manufactured with an alternative manufacturing method (e.g., such as spray coating).

In one implementation, the polymer composition 100 can exhibit a set of optical properties including a haze value equivalent or less than 1.3 percent and a yellowness index equivalent or less than 1.1. In this implementation, the haze value can be measured according to ASTM D1003, Procedure A, with Illuminant C. The Yellowness Index can be measured according to ASTM D1925 with a 2-degree observer angle and Illuminant C.

Additionally, the polymer composition 100 can exhibit a surface roughness below a threshold surface roughness such that the haze value—which may be impacted by changes in surface roughness—falls below 1.3 percent. Therefore, the polymer composition 100 can exhibit a surface roughness less than 40 nanometers. In one example, the polymer composition 100 can exhibit: a haze value less than 1.25 percent; a yellowness index equivalent or less than 1.0; a surface roughness represented by an arithmetic mean deviation (or “Ra”) between 5 nanometers and 40 nanometers; and a thickness between 5 micrometers and 120 micrometers.

Further, the polymer composition 100 can exhibit the set of optical properties including a UV resistance characterized by: a haze ratio between −20 percent and 20 percent after 72 hours of UV exposure; and a delta yellowness index between zero and 1.5 after 72 hours of UV exposure.

For example, the haze ratio of the polymer composition 100 can be characterized by: at a first time prior to a test period, measuring an initial haze value of the polymer composition 100; during the test period, exposing the polymer composition 100 to UV light for 72 hours; at a second time succeeding the test period, measuring a final haze value of the polymer composition 100; and, calculating a haze ratio of the polymer composition 100 as a ratio of the final haze value to the initial haze value. Additionally, the haze ratio can be expressed as a percentage by converting this ratio, of the final haze value to the initial haze value, to a percentage (e.g., by multiplying by 100 percent) and subtracting 100 percent.

Similarly, the delta yellowness index of the polymer composition 100 can be characterized by: at a first time prior to a test period, measuring an initial yellowness index of the polymer composition 100; during the test period, exposing the polymer composition 100 to UV light for 72 hours; at a second time succeeding the test period, measuring a final yellowness index of the polymer composition 100; and, calculating the delta yellowness index of the polymer composition 100 as a difference between the initial yellowness index and the final yellowness index.

In particular, in one example, to characterize the delta yellowness index of the polymer composition 100, a portion (e.g., a two-inch by two-inch film) of the polymer composition 100 can be extracted (e.g., cut) for analysis. This portion of the polymer composition 100 can then be: set on an acrylate sheet; and, together with the acrylate sheet, placed within a UV test chamber including a UV lamp defining a distance of approximately (e.g., within one centimeter) 15 centimeters between the portion of the polymer composition 100 and the UV lamp and defining a power output of approximately (e.g., within 5 percent) 15 Watts. Once the portion of the polymer composition 100 is placed within the UV test chamber, the portion of the polymer composition 100 can be exposed to UV light by powering on the UV lamp. In this example, the portion of the polymer composition 100 can be removed from UV exposure at set intervals to measure a series of yellowness index values, such as at zero hours, 24 hours, 48 hours, and 72 hours. The delta yellowness index can then be measured as a difference between a final yellowness index value, in the series of yellowness index values, recorded at 72 hours and a first yellowness index value, in the series of yellowness index values, recorded at zero hours.

Additionally, in this example, the portion of the polymer composition 100 can be removed from UV exposure at these set intervals to measure a series of haze values. The haze ratio can then be measured as a ratio of a final haze value, in the series of haze values, recorded at 72 hours, to a first haze value, in the series of haze values, recorded at zero hours. The delta haze ratio can then be represented as a percentage by converting this ratio, of the final haze value to the first haze value, to a percentage (e.g., by multiplying by 100 percent) and subtracting 100 percent.

Further, the polymer composition 100 can exhibit the set of optical properties including a temperature resistance characterized by: a first haze ratio between −20 percent and 20 percent after 5 weeks of storage at −10 degrees Celsius; a second haze ratio between −20 percent and 20 percent after 5 weeks of storage at 23 degrees Celsius; and a third haze ratio between −20 percent and 20 percent after 5 weeks of storage at 50 degrees Celsius.

For example, the first haze ratio of the polymer composition 100 can be characterized by: at a first time prior to a first test period, measuring an first initial haze value of the polymer composition 100; during the test period, storing the polymer composition 100 at −10 degrees Celsius for a duration of 5 weeks; at a second time succeeding the test period, measuring a first final haze value of the polymer composition 100; and, calculating a first haze ratio of the polymer composition 100 as a ratio of the first final haze value to the first initial haze value. Further, the second haze ratio of the polymer composition 100 can be characterized by: at a first time prior to a second test period, measuring a second initial haze value of the polymer composition 100; during the second test period, storing the polymer composition 100 at 50 degrees Celsius for a duration of 5 weeks; at a second time succeeding the second test period, measuring a second final haze value of the polymer composition 100; and, calculating a second haze ratio of the polymer composition 100 as a ratio of the second final haze value to the second initial haze value. The third haze ratio can be calculated by implementing similar techniques.

In one variation, the polymer composition 100 can include a proportion of a UV absorber configured to increase UV resistance of the polymer composition 100. In particular, the polymer composition 100 can include the proportion of the UV absorber to minimize the delta yellowness index of the polymer composition 100, such that the polymer composition 100 exhibits increased resistance to UV exposure. In one implementation, the polymer composition 100 can include a proportion of benzotriazoles as the proportion of the UV absorber. In another implementation, the polymer composition 100 can include a proportion of antioxidants as the proportion of the UV absorber. In yet another implementation, the polymer composition 100 can include a proportion of hindered amine stabilizers as the proportion of the UV absorber. Additionally and/or alternatively, the polymer composition 100 can include any combination of benzotriazoles, antioxidants, and/or hindered amine stabilizers as the proportion of the UV absorber.

### 5. Prepolymer Properties

The prepolymer form of the polymer composition 100 also exhibits qualities that are favorable to thin-film manufacturing techniques, such as a roll-to-roll manufacturing process. Therefore, the prepolymer form of the polymer composition 100 exhibits: low viscosity, thereby enabling the prepolymer mixture to be distributed via a slot-die and to self-level within a reasonable manufacturing time; solubility in commonly used organic solvents in the coatings field; low surface tension such that the prepolymer mixture cures without the appearance of flow lines and other surface defects; and a sufficiently long pot-life to enable coating with a slot die.

The prepolymer form of the polymer composition 100 exhibits a viscosity less than 3500 centipoise, such that a thin film of the polymer composition 100 can be coated and fully or partially cured using a roll-to-roll manufacturing process. The viscosity of the prepolymer form of the polymer composition 100 is controlled by adjusting the weight percentage in a solvent (e.g., a smaller weight percent resulting in a lower viscosity), which may be adjusted between 20% and 80% solids, depending on the particular solvent included in the prepolymer mixture; solvent type, and the bulk molecular weight of the components of the prepolymer form of the polymer composition 100.

The prepolymer form of the polymer composition 100 also exhibits a low surface tension due to the inclusion of additives, including but not limited to surfactants, de-foamers, self-leveling agents, and/or wetting agents. Therefore, the polymer composition 100 exhibits a negative correlation between the weight percentage of the additives and the surface tension of the prepolymer mixture.

Furthermore, the prepolymer form of the polymer composition 100 also exhibits a tuned pot-life that is long enough such that the prepolymer mixture can be coated using a slot-die without curing prematurely, while also being short enough to mitigate any imprinting defects due to insufficient curing and/or incomplete drying during the combined drying/curing process. The pot-life of the prepolymer mixture is controlled by: the weight proportion and chemistry of the catalyst; temperature; the weight proportion of the aliphatic or mixture of aliphatic and aromatic polyisocyanate 120; the overall solids content (i.e. the number of reactive species) of the prepolymer; and the ratio of polyurea linkage to polyurethane linkage generating groups in the prepolymer.

However, the prepolymer form of the polymer composition 100 can be tuned to exhibit different viscosities, different surface tensions, and/or different pot-lives for other polymer manufacturing processes, such as spray-coating, dip-coating, moulding, compressing, transferring, injecting, blowing, or other roll-to-roll processes such as gravure, reverse gravure, micro gravure, reverse roll, flex bar, rod, wire bar, knife over roll coating, etc.

### 6. Hybrid Copolymer Composition

As shown in FIGS. 1A and 1B, the polymer composition 100 is a crosslinked copolymer containing hard polymer segments and soft polymer segments resulting from the polymerization of molecular components including: a first proportion of polyisocyanate-terminated polyol 110; a second proportion of additional polyisocyanates 120; a third proportion of curative 130 (or “chain length extender”); a fourth proportion of soft polymer chain 140; and a fifth proportion of high functionality crosslinker 150. The polymer composition 100 can also include a catalyst and additives, such as wetting agents, de-foamers, surfactants, etc. to improve the prepolymer properties of the polymer composition 100, as described above, for thin film manufacturing techniques.

In one implementation, the polymer composition 100 includes an aliphatic-diisocyanate-terminated polyol 111 as the polyisocyanate-terminated polyol 110, a mixture of aliphatic polyisocyanate and aromatic polyisocyanate 121 as the additional polyisocyanates 120, an aromatic diamine curative 131 as the curative 130, a polyester polyol 141 as the soft polymer chain 140, and a high functionality dendrimer 151 as the high functionality crosslinker 150. Thus, in this implementation, the polymer composition 100 includes: a first proportion of an aliphatic-diisocyanate-terminated polyol 111; a second proportion including aliphatic polyisocyanate and aromatic polyisocyanate 121; a third proportion of an aromatic diamine curative 131 configured to extend a chain length of the aliphatic-diisocyanate-terminated polyol 111, the aliphatic polyisocyanate, and the aromatic polyisocyanate; a fourth proportion of a polyester polyol 141 configured to polymerize with the aliphatic-diisocyanate-terminated polyol 111, the aliphatic polyisocyanate, and the aromatic polyisocyanate; and a fifth proportion of a high functionality dendrimer 151 configured to crosslink the aliphatic-diisocyanate-terminated polyol 111, the aliphatic polyisocyanate, and the aromatic polyisocyanate.

Different combinations of polymers and isocyanate terminations 114 can be included in these proportions of the polymer composition 100 in order to achieve the desired mechanical and optical characteristics. For example, in a first implementation, the polymer composition 100 can include: a 12-fold-hydrogenated-methylene-diphenyl-diisocyanate-terminated polybutylene adipate as the polyisocyanate-terminated polyol; an isophorone diisocyanate as the aliphatic polyisocyanate 120; hydroquinone bis(2-hydroxyethyl)ether as the curative 130; a polyester polyol 141 as the soft polymer chain 140; and a dendritic polyester polyol exhibiting a functionality of six as the high functionality crosslinker 150. Thus, in this implementation, the polymer composition 100 includes: a first proportion of 12-fold-hydrogenated-methylene-diphenyl-diisocyanate-terminated polybutylene adipate; a second proportion of isophorone diisocyanate; a third proportion of hydroquinone bis(2-hydroxyethyl)ether; a fourth proportion of a polyester polyol 141; and a fifth proportion of a dendritic polyester polyol exhibiting a functionality of six.

In a second implementation, the polymer composition 100 can include: a 12-fold-hydrogenated-methylene-diphenyl-diisocyanate-terminated poly(tetramethylene ether) glycol as the polyisocyanate-terminated polyol 110; a mixture of 12-fold-hydrogenated-methylene-diphenyl-diisocyanate 122 and a tetramethylxylene diisocyanate 123 as the additional polyisocyanate; a set of isomers of diethyl toluene diamine 131 as the curative 130; a polycaprolactone polyol diol 141 as the soft polymer chain 140; and a dendritic polyester polyol 151 exhibiting a functionality greater than five as the high functionality crosslinker 150. Thus, in this implementation, the polymer composition 100 includes: a first proportion of a 12-fold-hydrogenated-methylene-diphenyl-diisocyanate-terminated poly(tetramethylene ether) glycol 111; a second proportion of additional polyisocyanates 120 including a first quantity of 12-fold-hydrogenated-methylene-diphenyl-diisocyanate 122 and a second quantity of tetramethylxylene diisocyanate 123; a third proportion of a set of isomers of diethyl toluene diamine 131; a fourth proportion of a polycaprolactone polyol diol 141; and a fifth proportion of an alcohol-terminated dendrimer 151 exhibiting a functionality greater than five.

In a third implementation, the polymer composition 100 can include: an isophorone diisocyanate poly(tetramethylene ether)glycol as the polyisocyanate-terminated polyol 110; a mixture of tetramethylxylene diisocyanate 123 and 12-fold-hydrogenated-methylene-diphenyl-diisocyanate 122 as the additional polyisocyanate 120; diethyl toluene diamine 131 as the curative 130; a linear polyester diol as the soft polymer chain 140; a dendritic polyester polyol exhibiting a functionality of sixteen as the high functionality crosslinker 150. Thus, in this implementation, the polymer composition 100 includes: a first proportion of isophorone diisocyanate poly(tetramethylene ether) glycol; a second proportion of additional polyisocyanates 120 including a first quantity of tetramethylxylene diisocyanate 123 and a second quantity of 12-fold-hydrogenated-methylene-diphenyl-diisocyanate 122; a third proportion of diethyl toluene diamine 131; a fourth proportion of a linear polyester diol; and a fifth proportion of a dendritic polyester polyol exhibiting a functionality greater than sixteen.

Various implementations of the polymer composition 100 can contain different weight percentages of each of the aforementioned components depending on the desired properties of both the prepolymer form and polymerized form of the polymer composition 100. However, in implementations of the polymer composition 100 for use as a protective film layer 102 or sponge layer 103 in an foldable electronic display, the polymer composition 100 can include: a first weight proportion of polyisocyanate-terminated polyol 110 between 50% and 90%; a second weight proportion of additional polyisocyanates 120 of up to 10%; a third weight proportion of a curative 130/chain length extender between 2% and 25%; a fourth weight proportion of a soft polymer chain 140 of up to 30%; and a fifth weight proportion of high functionality crosslinker 150 of up to 5%. In implementations of the polymer composition 100 that include the catalyst, the polymer composition 100 can include a sixth proportion of the catalyst of up to 2%. In implementations of the polymer composition 100 that include additives, the polymer composition 100 can include a seventh weight proportion of additives of up to 3%. In implementations of the polymer composition 100 that are colored, the polymer composition 100 can include an eighth proportion of nanoparticle pigment and/or organic colored dyes between 1% and 15% by weight. In another implementation, the polymer composition 100 can include an eighth proportion of particles of pigment and/or organic colored dyes between 1% and 20% by weight (e.g., of the total weight of the polymer composition 100). In this implementation, the eighth proportion of particles of pigment can include particles exhibiting sizes within a range of 5 nanometers to 500 nanometers.

In one implementation, the polymer composition 100 includes: fifty-five percent to eighty percent of the first proportion of polyisocyanate-terminated polyol 110 by weight; one percent to ten percent of the second proportion of additional polyisocyanate 120 by weight; one percent to ten percent of the third proportion of the curative 130 by weight; fifteen percent to thirty percent of the fourth proportion of the soft polymer chain 140 by weight; and zero to five percent of the fifth proportion of the high functionality crosslinker 150 by weight. Further, the polymer composition 100 can include up to one percent of a sixth proportion of a catalyst (e.g., dibutyltin dilaurate) by weight.

The polymer composition 100 is a polyurethane-polyurea polymer composition including the aforementioned components which polymerize to form crosslinked hard polymer segments and soft polymer segments via a first number of urethane linkages 104 and a second number of urea linkages 106. The urethane linkages connect (i.e. chemically bond): the polyol chains 116 of the polyisocyanate terminated polyol no to the polyisocyanate terminations 114 of the polyisocyanate terminated polyol 110; the soft polymer chain 140 to the polyisocyanate terminations 114 and the additional polyisocyanates 120; and the high functionality crosslinker to the polyisocyanate terminations 114 and the additional polyisocyanates 120. The urea linkages 106 connect the curative 130 to the polyisocyanate terminations 114 and the additional polyisocyanates 120.

Thus, polyurethane groups link soft polymer segments (including the polyisocyanate terminated polyol no, the soft polymer chain 140, and the additional polyisocyanates 120) within the polymer composition 100 and crosslink (e.g., via the high functionality crosslinker) the soft polymer segments with the hard polymer segments while polyurea groups link the hard polymer segments (including the curative 130, the additional polyisocyanates 120, and the polyisocyanate terminations) within the polymer composition 100. The copolymerization of these multiple forms of soft polymer segments in the polymer composition 100 prevents the polymer composition 100 from hardening at lower temperatures while the inclusion of the hard polymer segments in the polymer composition 100 maintains the rigidity of the polymer composition 100 at higher temperatures.

More specifically, the polymer composition 100 can include a tuned ratio of urethane linkages 104 to urea linkages 106. The urethane linkages 104 in the polymer composition 100 connect a first quantity of polyether polyol 116 segments to a second quantity of aliphatic diisocyanate terminations 114; connect a third quantity of polyester polyol 141 segments to the second quantity of the aliphatic diisocyanate terminations 114 and a fourth quantity of additional diisocyanates 120; and connect a fifth quantity of a high functionality crosslinker 150 to the second quantity of the aliphatic diisocyanate terminations 114 and the fourth quantity of additional diisocyanates 120. The urea linkages 106 in the polymer composition 100 connect a sixth quantity of an aromatic polyamine curative 131 to the second quantity of the aliphatic diisocyanate terminations 114 and the fourth quantity of additional diisocyanates 120.

The polymer composition 100 is configured to include both urethane linkages 104 and urea linkages 106 in order to achieve the desired mechanical properties (e.g., storage modulus, tensile modulus, bendability) and optical clarity (e.g., optical transmission, void size and fraction). Thus, the polymer composition 100 can also define a ratio of urethane linkages 104 to urea linkages 106 that yields these desired properties. For example, the polymer composition 100 can define a molar ratio of urethane linkages 104 to urea linkages 106 between two-to-five and six-to-five.

However, the polymer composition 100 can also include additional components or modified proportions of the above components that may improve the properties of the polymer composition 100 when applied as a protective layer in a foldable electronic display.

### 6.1 Polyisocyanate-Terminated Polyol

The polymer composition 100 includes a first proportion of polyisocyanate-terminated polyol 110 (e.g., a polyester, polycaprolactone, polyether, polyacrylate, or polycarbonate) as the largest weight proportion of the polymer composition 100. For example, the polymer composition 100 can include between fifty-five percent and eighty percent of the first proportion of polyisocyanate-terminated polyol 110 by weight. The polyisocyanate-terminated polyol 110 includes two subcomponents in each prepolymer chain: the polyisocyanate-terminations 114 and the polyol chain 116. The polyisocyanate-terminations 114 function as a component in hard polymer segments of the polymer composition 100, when reacted with the curative 130, the soft polymer chain 140, and/or the high functionality crosslinker 150, while the polyol chain ii6 functions as a soft linkage between the hard segments. When reacted, the polyisocyanate-terminations and the polyol chain 116 bond to form urethane linkages. In one implementation, the polyisocyanate-terminated polyol no includes a diisocyanate-terminated polyether polyol with an average molecular weight between 650 and 2600 g/mol. In a second implementation, the polyisocyanate-terminated polyol no includes a diisocyanate-terminated polyester polyol with an average molecular weight between 500 and 2600 g/mol. Thus, the polyisocyanate-terminated polyol no provides the chemical backbone of the polymer composition 100.

The polymer composition 100 can include different quantities of different average molecular weight of the polyol chain 116 in the first proportion of the polyisocyanate-terminated polyol 110. In one implementation, the polymer composition 100 includes a first proportion of a polyisocyanate-terminated polyol no including: a first quantity of the polyol chain 116 exhibiting a first average molecular weight; and a second quantity of the polyol chain 116 exhibiting a second average molecular weight. Further, based on the first quantity of the polyol chain 116 and the second quantity of the polyol chain 116, the polymer composition 100 can exhibit a low temperature storage modulus between 300 MPa and 1400 MPa and a high temperature storage modulus between 10 MPa and 100 MPa.

In one implementation, the polymer composition 100 exhibits properties of a copolymer including both lower average molecular weight polyols (e.g., 650 g/mol) and higher average molecular weight polyols (e.g., 2,000 g/mol) by including blends of the polyisocyanate-terminated polyol 110 including polyol chains 116 with a range of molecular weights. For example, the polymer composition 100 can include a first proportion of aliphatic-diisocyanate-terminated polyol 111 including: a first quantity of polyol chain 116 exhibiting an average molecular weight of 650 g/mol; a second quantity of polyol chain 116 exhibiting an average molecular weight of 1,000 g/mol; and a third quantity of polyol chain 116 exhibiting an average molecular weight of 2,000 g/mol. Thus, by including varying average molecular weights, the polymer composition 100 can exhibit properties of both lower average molecular weight and higher average molecular weight polyols.

The average molecular weight of the first proportion of polyisocyanate-terminated polyol 110 may be increased to lower the low temperature storage modulus of the polymer composition 100. For example, the polymer composition 100 can include: a first proportion of an aliphatic-diisocyanate-terminated polyol 111 including a first quantity of the polyol chain 116 characterized by an average molecular weight of 650 g/mol, the first quantity defining between ninety percent and one-hundred percent of the first proportion by weight. The polymer composition 100 can exhibit: a low temperature storage modulus between 900 MPa and 1400 MPa; and a high temperature storage modulus between 20 MPa and 30 MPa. Alternatively, in another example, the polymer composition 100 can include a first proportion of an aliphatic-diisocyanate-terminated polyol 111: including a first quantity of the polyol chain 116 characterized by an average molecular weight of 650 g/mol, the first quantity defining between sixty percent and eighty percent of the first proportion by weight; and a second quantity of the polyol chain 116 characterized by an average molecular weight of 2000 g/mol, the second quantity defining between twenty percent and forty percent of the first proportion by weight. In this example, the polymer composition 100 can exhibit: a low temperature storage modulus between 500 MPa and 800 MPa; and a high temperature storage modulus between 15 MPa and 25 MPa. Thus, the low temperature modulus of the polymer composition 100 may be lowered by increasing the average molecular weight of the polyisocyanate-terminated polyol 110.

The polymer composition 100 can include a polyisocyanate-terminated polyol 110 with polyisocyanate-terminations with an overall functionality equal to or greater than two, where polyisocyanate-terminations with greater functionality increase the storage modulus of the polymer composition 100 by increasing the degree of crosslinking. In one implementation, the polymer composition 100 includes a diisocyanate-terminated polyol exhibiting an overall functionality of two, thus reducing the storage modulus of the polymer composition 100 at lower temperatures (e.g., −20° C.) when compared to polyisocyanates exhibiting higher overall functionality (e.g., greater than two). For example, the polymer composition 100 can: include a diisocyanate-terminated polyol exhibiting an overall functionality of two and including a polyol chain 116 bonded with a first diisocyanate on a first end and bonded with a second diisocyanate on a second end. The functional group of the diisocyanate terminations not bound to the polyol chain 116 can additionally bond to one of a curative 130, a soft polymer chain 140, or a high functionality crosslinker 150. In this implementation, the polymer composition 100 exhibits a low temperature storage modulus between 300 MPa and 1000 MPa.

Additionally, the polymer composition 100 can include a polyisocyanate-terminated polyol 110 with either aromatic or aliphatic polyisocyanate 120-terminations (or a blend thereof) depending on the desired characteristics of the polymer composition 100, wherein polyisocyanate-terminated polyol 110 including aromatic terminations are generally characterized by improved impact and scratch resistance and high-temperature bend performance, while polyisocyanate-terminated polyols no including aliphatic terminations are generally characterized by improved optical clarity, low-temperature bend performance, and longer pot-life. In one implementation, the polymer composition 100 includes a proportion of aromatic polyisocyanate-terminated polyol 110 and a proportion of aliphatic polyisocyanate-terminated polyol 110 to achieve more balanced characteristics representative of both aromatic and aliphatic-polyisocyanate terminations 114. In one implementation, as shown in FIG. 2, the polymer composition 100 includes a polyisocyanate-terminated polyol 110 terminated by 12-fold hydrogenated methylene diphenyl diisocyanate (hereinafter “H12 MDI”), which is an aliphatic diisocyanate. In alternative implementations, the polyisocyanate-terminated polyol 110 can include other isocyanate terminations 114, such as isophorone diisocyanate (hereinafter “IPDI”) and/or hexamethylene diisocyanate (hereinafter “HDI”).

The polyisocyanate-terminated polyol 110 can include a variety of polyol chains 116 common in various foldable polyurethanes, such as polyether polyols, polyester polyols, polycaprolactone polyols, polyacrylic polyols, and polycarbonate polyols. In one implementation, the polyisocyanate-terminated polyol 110 includes poly(tetramethylene ether) glycol (hereinafter “PTMEG”) as the polyol chain 116.

In one implementation, as shown in FIG. 2, the polymer composition 100 includes H12 MDI terminated PTMEG as the polyisocyanate-terminated polyol 110. In a second implementation, the polymer composition 100 includes H12 MDI terminated polybutylene adipate (polyester) as the polyisocyanate terminated polyol.

In one variation, the first proportion of polyisocyanate-terminated polyol 110 further includes polyol chains 116 terminated by a first set of diisocyanates; and a second set of diisocyanates (e.g., additional isocyanates 120) configured to promote polymerization of the third proportion of the curative 130, the fourth proportion of soft polymer chains 140, and the fifth proportion of the high functionality crosslinker 150. For example, the polymer composition 100 can include the first proportion of aliphatic-diisocyanate-terminated polyol in including polyol chains 116 terminated by a first set of aliphatic diisocyanates and a second set of aliphatic diisocyanates configured to promote polymerization of the third proportion of the curative 130, the fourth proportion of the soft polymer chains 140, and the fifth proportion of the high functionality crosslinker; and exhibiting a molar ratio of the first set of diisocyanates to the second set of diisocyanates between two and four. In this example, the second set of aliphatic diisocyanates perform a similar function (e.g., promote polymerization between soft segments and/or hard segments) to the second proportion of the aliphatic polyisocyanate 120, as described below.

### 6.2 Additional Polyisocyanates

The polymer composition 100 includes a second proportion of additional polyisocyanates 120 configured to increase mechanical strength and rigidity of the polymer composition 100. More specifically, the polymer composition 100 includes a second proportion of additional polyisocyanates 120 (i.e. polyisocyanates that do not terminate polyol chains as described above) and can include a quantity of aliphatic polyisocyanates or a mixture of a quantity of aliphatic polyisocyanates and a quantity of aromatic polyisocyanates. The inclusion of the additional polyisocyanates 120 functions to further modify the hard polymer segments and soft polymer chains 140 to achieve specific material property targets, such as increased scratch and/or impact resistance (in implementations of the polymer composition 100 including the additional polyisocyanates includes aromatic isocyanates). Furthermore, the incorporation of sterically hindered urethane groups in the additional polyisocyanates 120 improves processability by reducing side reactions with water in the prepolymer mixture and enabling well-controlled reactions between the prepolymer mixture and hydroxyl and/or amine groups. The polymer composition 100 can include between one and ten percent of the aliphatic isocyanate by weight.

Like the polyisocyanate-terminated polyol 110, the additional polyisocyanates 120 can exhibit an overall functionality equal to or greater than two, wherein additional polyisocyanates 120 with greater functionality increase the storage modulus of the polymer composition 100 by increasing the degree of crosslinking. In one implementation, the polymer composition 100 includes an aliphatic diisocyanate as the additional polyisocyanate 120.

In one implementation, the polymer composition 100 can include H12 MDI, as the additional isocyanates 120, as the H12 MDI increases the storage modulus of the polymer composition 100 at high temperatures without substantially increasing the storage modulus at low temperatures. For example, the polymer composition 100 can include a second proportion of H12 MDI defining between two percent and twenty percent of a mixture of the first proportion and the second proportion by weight. In this example, the polymer composition 100 can include the second proportion of H12 MDI exhibiting a functionality of two and configured to polymerize with the third proportion of the curative 130/chain length extender, the fourth proportion of the soft polymer chain 140, and/or fifth proportion of the high functionality crosslinker 150. Therefore, in this implementation, the polymer composition 100 can include both a first proportion of H12 MDI terminated polyol including H12 MDI terminations, and a second proportion of H12 MDI as the additional polyisocyanates 120.

In another implementation, polymer composition 100 can include IPDI as the additional polyisocyanates 120, as IPDI can increase the tensile and storage modulus of the polymer composition 100 without substantially increasing the storage modulus at low temperatures. Furthermore, IPDI reduces the viscosity of the prepolymer mixture compared to prepolymer mixtures containing H12 MDI.

In another implementation, as shown in FIG. 2, the polymer composition 100 can include a quantity of tetramethylxylene diisocyanate (hereinafter “TMXDI”), as the TMXDI has a low reactivity when compared to aliphatic polyisocyanates such as H12 MDI, and imparts UV stability to the polymer composition 100. Additionally, TMXDI increases the storage modulus of the polymer composition 100 at high temperatures without substantially increasing the storage modulus at low temperatures by improving the stiffness of hard segments in the polymer composition 100. Furthermore, TMXDI reduces the viscosity of the prepolymer mixture more effectively than other common aliphatic polyisocyanates and prevents discoloration of the polymer composition 100 (e.g., yellowing of the protective film layer 102).

In yet another implementation, the polymer composition 100 includes both TMXDI and excess H12 MDI (i.e. H12 MDI that does not terminate the polyisocyanate-terminated polyol 110) providing a mixture of the abovementioned properties of the polymer composition 100 when including TMXDI and H12 MDI separately. For example, the polymer composition 100 can include a second proportion of aliphatic polyisocyanate 120 including a mixture of TMXDI and H12 MDI, the second proportion configured to: increase the tensile and storage modulus of the polymer composition 100 without substantially increasing the storage modulus at low temperatures; impart UV stability to the polymer composition 100; and reduce the viscosity of the prepolymer mixture. In this implementation, the polymer composition 100 can include between zero percent and fifteen percent additional H12 MDI by weight and between zero and ten percent TMXDI by weight. The polymer composition 100 can include the second proportion of aliphatic isocyanate defining a molar ratio of excess H12 MDI to TMXDI between 0.8 and 2.0. For example, the polymer composition 100 can include the second proportion of aliphatic isocyanate defining a molar ratio of excess H12 MDI to TMXDI of one.

### 6.3 Curative and Chain Length Extender

The polymer composition 100 includes a third proportion of the curative 130/chain length extender. The curative 130 functions to extend the chain length of hard segments, which include the polyisocyanate terminations 114 of the polyisocyanate-terminated polyols 110 and the aliphatic polyisocyanate 120, by binding with polyisocyanate terminations 114 via polyurethane bonds and polyurea bonds. Thus, the inclusion of greater proportions of the curative 130 relative to the soft polymer chain 140 of the polymer composition 100 increases the storage modulus of the polymer composition 100.

In one example, the polymer composition 100 can: include a third proportion of the curative 130 defining eleven percent of the polymer composition 100 by weight; and include a fourth proportion of the soft polymer chain 140 defining eighteen percent of the polymer composition 100 by weight. In this example, the polymer composition 100 exhibits a low temperature storage modulus between 700 MPa and 1400 MPa at −20 degrees Celsius; a high temperature storage modulus between 15 MPa and 40 MPa at 85 degrees Celsius; and a room temperature storage modulus between 50 MPa and 400 MPa at 20 degrees Celsius.

In another example, the polymer composition 100 can: include a third proportion of the curative 130 defining eight percent of the polymer composition 100 by weight; and include a fourth proportion of the soft polymer chain 140 defining twenty-five percent of the polymer composition 100 by weight. In this example, the polymer composition 100 exhibits a low temperature storage modulus between 500 MPa and 800 MPa at −20 degrees Celsius; and a high temperature storage modulus between 20 MPa and 30 MPa at 85 degrees Celsius. Therefore, the polymer composition 100 can exhibit a varying range of low temperature and high temperature storage modulus based on the ratio of the curative 130 to the soft polymer chain 140 included in the polymer composition 100.

In yet another example, the polymer composition 100 includes the third proportion of the curative 130 defining between zero percent and ten percent of the polymer composition 100 by weight and exhibits a high temperature storage modulus between 15 MPa and 35 MPa at 85 degrees Celsius. More specifically, where the polymer composition 100 includes a lower weight percent of the curative 130 between zero percent and five percent, the polymer composition 100 exhibits a high temperature storage modulus between 15 MPa and 25 MPa at 85 degrees Celsius. Alternatively, where the polymer composition 100 includes between five percent and ten percent of the curative 130 by weight, the polymer composition 100 exhibits a high temperature storage modulus between 25 MPa and 35 MPa at 85 degrees Celsius.

The polymer composition 100 can include a curative 130 with a low molecular weight (e.g., less than 200 g/mol) configured to increase the number of urethane and/or urea groups per unit length of the polymer composition 100. For example, the polymer composition 100 can include curatives/chain length extenders such as 1,4 butanediol (e.g., with an average molecular weight of 98.12 g/mol), 2-methyl-1,3-propanediol, diethylene glycol, 1,5-pentanediol, or 1,6 hexanediol.

In one implementation, as shown in FIG. 2, the polymer composition 100 includes a polyamine curative such that hard segments of the polymer composition 100 include a polyurea chain, thus increasing the number of polyurea groups present in the polymer composition 100. Furthermore, the polymer composition 100 can include a diamine curative to promote the polymerization of linear polyurea segments 106 when compared to higher functional polyamine curatives. For example, the polymer composition 100 can include: a first proportion of H12 MDI terminated PTMEG; a second proportion of additional polyisocyanates (e.g., H12 MDI or H12 MDI and TMXDI); a third proportion of a diamine curative including an aromatic ring and two amine functional groups located opposite each other on the aromatic ring. The polymer composition 100 can be configured such that each amine functional group of the second proportion of the diamine curative forms a polyurea bond with a diisocyanate group of the first proportion of H12 MDI terminated PTMEG and/or with aliphatic isocyanates of the second proportion.

The polymer composition 100 can also include aromatic curatives, such as aromatic polyamine curatives or aromatic hydroxy-functional curatives, where aromatic polyamine curatives contribute polyurea bond structures to the polymer composition 100 and aromatic hydroxy-functional curatives contribute polyurethane bond structures. In one implementation, the polymer composition 100 includes one or more isomers of diethyl toluene diamine (hereinafter “DETDA”) as the curative 130, such as 3,5-diethyltoluene-2,4-diamine; 3,5-diethyltoluene-2,6-diamine; or a mixture of both. In this implementation, the polymer composition 100 can include a proportion of the curative 130 further including a mixture of approximately 80% 3,5-diethyltoluene-2,4-diamine and approximately 20% 3,5-diethyltoluene-2,6-diamine. Implementations of the polymer composition 100 including DETDA exhibit a high degree of crystallinity and improved high temperature properties when compared to other curatives. In one implementation, the polymer composition 100 includes an isomer of DEDTA (e.g., Ethacure 100) with an average molecular weight of 178.28 g/mol and defining between seven percent and ten percent of the polymer composition 100 by weight. In this example, the polymer composition 100 can exhibit a storage modulus greater than 20 MPa at 85 degrees Celsius.

In another implementation, the polymer composition 100 includes hydroquinone bis(2-hydroxyethyl)ether, ethoxylated hydroquinone bis(2-hydroxyethyl)ether or mixtures thereof to enable well-controlled reactions between the prepolymer mixture and curative when compared to compositions including DETDA.

### 6.4 Soft Polymer Chain

The polymer composition 100 includes a fourth proportion of a soft polymer chain 140 to prevent excess hardening of the polymer composition 100 at low temperatures. The properties of the soft polymer chain 140, such as its weight percentage within the polymer composition 100, molecular weight, and chemical backbone type of the soft polymer chain 140 can contribute to the storage modulus characteristics of the polymer composition 100. In particular, the molecular weight and composition of the soft polymer chain 140 significantly impact the low temperature storage modulus (e.g., the storage modulus at or below 20 degrees Celsius) of the polymer composition 100. Furthermore, in one implementation, a mixture of soft polymer chain 140 backbone chemistries is utilized to control the extent of crystallization of the soft polymer chains 140 at low temperatures and thus control the flexibility of the polymer composition 100 at low temperatures. In one implementation, the polymer composition 100 includes between fifteen percent and thirty percent of the fourth proportion of the soft polymer chain 140 by weight.

The polymer composition 100 can include a secondary polyol as the soft polymer chain 140 that is configured to control crystallization of the polyol chains 116 of the polyisocyanate-terminated polyol no by intermixing with the polymer chains of the chain extended polyisocyanate-terminated polyol 110. Thus, the soft polymer chain 140 can reduce the storage modulus of the polymer composition 100 at low temperatures without substantially reducing the storage modulus at high temperatures because crystallization of the polyol chains 116 does not occur at high temperatures. For example, the polymer composition 100 can include a fourth proportion of the soft polymer chain 140 defining twenty weight percent of the polymer composition 100. The polymer composition 100 can exhibit a low temperature storage modulus between 800 MPa and 1400 MPa at −20 degrees Celsius and a high temperature storage modulus between 20 MPa and 40 MPa at 85 degrees Celsius. Alternatively, in another example, the polymer composition 100 can include a fourth proportion of the soft polymer chain 140 defining thirty weight percent of the polymer composition 100. The polymer composition 100 can exhibit a low temperature storage modulus between 500 MPa and 800 MPa at −20 degrees Celsius and a high temperature storage modulus between 20 MPa and 40 MPa at 85 degrees Celsius.

In one implementation, as shown in FIG. 2, the polymer composition 100 includes a polyester polyol 141 as the soft polymer chain 140, which can further improve the chemical stability of the polymer composition 100. In a second implementation, the polymer composition 100 includes a polycaprolactone polyol diol with an average molecular weight between 330 and 1000 g/mol as the soft polymer chain 140, which can increase wear resistance, gloss, and UV resistance in addition to decreasing the low temperature storage modulus of the polymer composition 100. Alternatively, the polymer composition 100 can include other linear polyester diols with an average molecular weight between 500 and 2000 g/mol.

### 6.5 High Functionality Crosslinker

The polymer composition 100 includes a fifth proportion of the high functionality crosslinker 150. The high functionality crosslinker 150 functions to increase the crosslinking density of the polymer composition 100, thereby improving the high temperature storage modulus of the polymer composition 100. The polymer composition 100 can include a high functionality crosslinker 150 characterized by functionalities between three and one hundred depending on the desired high temperature shear modulus. For example, the polymer composition 100 can include a first high functionality crosslinker 150 characterized by a functionality of five and exhibiting a high temperature storage modulus between 15 MPa and 30 MPa at 85 degrees Celsius. Alternatively, the polymer composition 100 can include a second high functionality crosslinker 150 characterized by a functionality of twenty and exhibiting a high temperature storage modulus between 25 MPa and 40 MPa at 85 degrees Celsius.

In one implementation, as shown in FIG. 2, the polymer composition 100 includes a dendritic polyester polyol as the high functionality crosslinker 150, which, in comparison to a low functionality crosslinker, results in higher crosslinking density in the polymer composition 100 for a given weight proportion of crosslinker. Furthermore, the dendritic polyester polyol encourages spatially heterogeneous crosslinking within the soft polymer chain 140 when compared to a low functionality crosslinker used to achieve the same overall bulk crosslink density. The spatially heterogenous crosslinks may improve the low-temperature flexibility of the polymer composition 100 by providing a relatively wider distribution of average molecular weight between crosslinks in the polymer composition 100 when compared to lower functionality crosslinkers. In one implementation, the polymer composition 100 includes a dendritic polyester polyol with a functionality of twenty-three as the high functionality crosslinker 150. In a second implementation, the polymer composition 100 includes a dendritic polyester polyol with a functionality of sixteen as the high functionality crosslinker 150. In a third implementation, the polymer composition 100 includes a dendritic polyester polyol with a functionality of six as the high functionality crosslinker 150.

### 6.6 Catalyst

The polymer composition 100 can also include a sixth proportion of a catalyst. The catalyst functions to promote (during polymerization of the polymer composition 100) polyol-isocyanate and/or amine-isocyanate reactions in order to balance the pot-life and reactivity of the prepolymer mixture for a roll-to-roll manufacturing process. Thus, the polymer composition 100 can include any catalyst that promotes urethane and/or urea reactions. In one implementation, the polymer composition 100 includes tetravalent diorganotins, such as dibutyltin dilaurate (hereinafter “DBTDL”), as the catalyst. In a second implementation, the polymer composition 100 includes organozincs, such as zinc neodecanoate, as the catalyst. In a third implementation, the polymer composition 100 includes blends of zinc and bismuth catalysts, such as zinc and bismuth carboxylate, as the catalyst.

### 6.7 Surface Additive

The polymer composition 100 can also include a seventh proportion of a surface additive. The surface additive functions to reduce the surface tension of the prepolymer mixture of the polymer composition 100, thereby improving the surface quality of the cured film of polymer composition 100. In one implementation, the polymer composition 100 includes a silicone oil surface additive such that the surface additive can be added to the prepolymer mixture of the polymer composition 100 independent on the specific solvents included in the prepolymer mixture of the polymer composition 100. In a second implementation, the polymer composition 100 includes polyether-modified polydimethylsiloxane, which can prevent cratering and increase gloss in a thin film of the polymer composition 100. Additional examples of surface additives include, but are not limited to, wetting agents, de-foamers, surfactants, etc.

### 6.8 Prepolymer Solvents

The prepolymer form of the polymer composition 100 can include a solvent at between 20% and 80% weight proportion of the prepolymer mixture depending on the manufacturing method and desired drying properties of the prepolymer mixture. The prepolymer form of the polymer composition 100 can include a solvent or combination of solvents in which the prepolymer form of the polymer composition 100 exhibits sufficient solubility, such as a ketone solvent. More specifically the prepolymer form of the polymer composition 100 can include methyl isobutyl ketone (MIBK), cyclohexanone, acetone, and/or MEK. The prepolymer form of the polymer composition 100 can include an aprotic, polar organic solvent, in order to reduce the viscosity of the prepolymer form of the polymer composition 100. In one implementation, the solvent can also contain smaller proportions of toluene and/or cyclohexanone to improve coating quality during the drying process.

Furthermore, in some manufacturing processes, the prepolymer form of the polymer composition 100 can include multiple component mixtures each with a different solvent and/or solvent proportions. For example, the prepolymer form of the polymer composition 100 can include a first mixture including the catalyst, the curative 130/chain extender, the soft polymer chain 140, surface additives, and the high functionality crosslinker 150, and a second mixture including the polyisocyanate-terminated polyol no and the aliphatic isocyanate 120. In this example, each of the two mixtures can include a different solvent.

### 7. Manufacturing

The polymer composition 100 can be manufactured via a continuous roll-to-roll process, described in further detail in U.S. patent application Ser. No. 15/895,971, that produces a thin layer exhibiting both chemical and physical cross-linking to yield clear optical properties and particular mechanical properties, such as resistance to impact, pencil hardness, etc.

The polymer composition 100 can be manufactured via a roll-to-roll manufacturing process including: mixing a first solution and a second solution to define a viscous material, the first solution including a first proportion of a polyisocyanate-terminated polyol 110, a second proportion of an aliphatic polyisocyanate 120, and a seventh proportion of the solvent, the second solution including a third proportion of a curative 130, a fourth proportion of a soft polymer chain 140, a fifth proportion of a high functionality crosslinker 150, and a sixth proportion of a catalyst; advancing a substrate from a first roll across a surface continuously at a first speed; depositing the first viscous material characterized by a first viscosity through a deposition head onto the substrate, the first viscous material flowing laterally across the substrate to form a thin layer of substantially uniform thickness over the substrate over a period of time while the substrate advances along the surface; heating the thin layer to remove solvent from the thin layer and to induce reaction between the prepolymer, the aliphatic polyisocyanate, the curative, the soft polymer chain, and the cross-linking agent and to cure the thin layer via physically and chemically cross-linked polymer chains.

In one implementation, the polymer composition 100 can be manufactured by mixing a first solution and a second solution before combining the first solution and the second solution. The first solution includes: twenty percent to eighty percent of the first proportion of aliphatic-diisocyanate-terminated polyol 111 and the second proportion of additional diisocyanates 121 by weight; and up to eighty percent of a first solvent by weight. The first solution can include between fifty percent to eighty percent of the total solid content of the polymer composition 100 by weight while the second solution can include twenty to fifty percent of the total solid content of the polymer composition 100 by weight. The second solution includes: twenty percent to eighty percent of the third proportion of an aromatic diamine curative 131, the fourth proportion of a polyester polyol 141, and the fifth proportion of a high functionality dendrimer 151; and up to eighty percent of a second solvent (which may be the same solvent as the first solvent or a different solvent). The polymer composition 100 can then be manufactured by combining the first solution and the second solution via a roll-to-roll manufacturing process (e.g., as described above) at a ratio between one-to-one and four-to-one by weight. Additionally, the polymer composition 100 can be manufactured by adding a sixth proportion of a catalyst (e.g., dibutyltin dilaurate) to the second solution before combining first solution and the second solution, the sixth proportion defining between zero percent and two percent of the polymer composition 100 by weight. For example, a first proportion of H12MDI terminated PTMEG as the aliphatic-polyisocyanate-terminated polyol 111 and a mixture of H12MDI and TMXDI as the second proportion of additional diisocyanates 121 can be mixed to form a first solution. The H12 MDI forms a defined hard segment in the final polymer composition 100, thus increasing the strength and high temperature storage modulus of the final polymer composition 100, while the PTMEG improves the elastomeric properties of the polymer composition 100. The TMXDI forms a hard segment, thus increasing the strength and rigidity of the polymer composition 100, while preventing color changes (e.g., preventing the protective film layer 102 from turning yellow). Separately, diethyltoluene diamine as the aromatic diamine curative 131, polycaprolactone diol as the polyester polyol 141, and an alcohol dendrimer as the high functionality dendrimer 151 can be mixed to form a second solution. The diethyltoluene diamine forms a well-defined hard segment in the final polymer composition 100, thus increasing strength of the polymer composition 100 at both low temperatures and high temperatures. The polycaprolactone diol disrupts the soft segment (e.g., PTMEG chains) morphology and lowers the low temperature storage modulus, thus counteracting the increase in low temperature storage modulus caused by the inclusion of TMXDI and diethyltoluene diamine. The alcohol dendrimer, when reacted with other components, forms a highly crosslinked polymer exhibiting large distances between cross-links, which enables the polymer composition 100 to remain relatively ductile at low temperatures and stable at high temperatures. The polymer composition 100 can be manufacture by mixing the first solution and the second solution via a roll-to-roll process, thus forming the polymer composition 100. The synergistic effects of each of these components enables the polymer composition 100 to exhibit increases in storage modulus at high temperatures and decreases in storage modulus at low temperatures, each independently of the other.

As a person skilled in the art will recognize from the previous detailed description and from the figures and claims, modifications and changes can be made to the embodiments of the invention without departing from the scope of this invention as defined in the following claims.

1. A polymer composition:
comprising a first amount of urethane linkages:
connecting a first quantity of polyol segments to a second quantity of a first subset of diisocyanates; and
connecting a third quantity of a crosslinker to a fourth quantity of a second subset of diisocyanates; and
comprising a second amount of urea linkages connecting a fifth quantity of a curative to a sixth quantity of a third subset of diisocyanates;
exhibiting an impact resistance characterized by a tan delta between 0.05 and 0.4 at temperatures between −20 degrees Celsius and 85 degrees Celsius.

2. The polymer composition of claim 1, wherein a film comprising the polymer composition exhibits no measurable permanent deformation after the film is repeatedly folded and unfolded around a 2-millimeter radius mandrel at a frequency of 1 Hz for greater than 200,000 cycles.

3. The polymer composition of claim 2, wherein the film is configured to form a protective film layer in a foldable electronic display, the foldable electronic display comprising:
the protective film layer:
comprising the polymer composition; and
exhibiting a first thickness between 5 micrometers and 120 micrometers; and
a hard coat layer:
comprising a resin material; and
exhibiting:
a water contact angle of a surface of the hard coat layer equivalent or greater than 110 degrees;
a pencil hardness equivalent or greater than H tested at a load of 250 grams; and
a second thickness between 2 micrometers and 30 micrometers.

4. The polymer composition of claim 2, wherein the film is configured to form a protective film layer in a foldable electronic display, the foldable electronic display comprising:
the protective film layer:
comprising the polymer composition; and
exhibiting a first thickness between 5 micrometers and 120 micrometers; and
a pressure sensitive adhesive layer:
comprising an adhesive material; and
exhibiting:
a room temperature storage modulus between 10 kPa and 250 kPa at 25 degrees Celsius;
a storage modulus between 10 kPa and 500 kPa at temperatures between −20 degrees Celsius to 85 degrees Celsius; and
a second maximum tan delta equivalent or less than 0.4; and
a second thickness between 5 micrometers and 50 micrometers.

5. The polymer composition of claim 4, wherein the foldable electronic display further comprises:
an optical layer exhibiting a third thickness between 5 micrometers and 100 micrometers;
a hard coat layer, exhibiting:
a water contact angle of a surface of the hard coat layer equivalent or greater than 110 degrees;
a pencil hardness equivalent or greater than H tested at a load of 250 grams; and
a second thickness between 2 micrometers and 30 micrometers.

6. The polymer composition of claim 5, wherein the laminated film comprises:
the hard coat layer comprising the resin material selected from the group comprising a (meth)acryl resin, an epoxy resin, a silicone resin, an oxetane resin, a urethane resin, a urethane (meth)acrylate resin;
the protective film layer arranged below the hard coat layer and above the optical layer;
the optical layer:
selected from the group comprising a polymer substrate and a glass substrate; and
arranged below the protective film layer and above the pressure sensitive adhesive layer; and
the pressure sensitive adhesive layer:
comprising the adhesive material comprising a resin; and
arranged below the optical layer.

7. The polymer composition of claim 1, comprising a molar ratio of the first amount of urethane linkages to the second amount of urea linkages between two-to-five and six-to-five.

8. The polymer composition of claim 1, exhibiting:
a haze value less than 1.3 percent;
a yellowness index less than 1.1; and
a surface roughness characterized by an arithmetic mean deviation between 5 nanometers and 40 nanometers.

9. The polymer composition of claim 1, exhibiting:
a low-temperature storage modulus between 300 MPa and 1400 MPa at −20 degrees Celsius; and
a high-temperature storage modulus between 10 MPa and 100 MPa at 85 degrees Celsius.

10. The polymer composition of claim 9, exhibiting:
a first modulus ratio between two percent and twenty percent after 5 weeks in storage at −10 degrees Celsius;
a second modulus ratio between two percent and twenty percent after 5 weeks of storage at 23 degrees Celsius; and
a third modulus ratio between two percent and twenty percent after 5 weeks in storage at 50 degrees Celsius.

11. The polymer composition of claim 1, exhibiting:
a bulk density between 1.1 and 1.4 g/cm³; and
a void fraction between three and twenty percent.

12. The polymer composition of claim 1, exhibiting a tan delta curve characterized by a full width at half maximum between 70 degrees Celsius and 180 degrees Celsius.

13. A polymer composition:
comprising:
a first proportion of polyol segments;
a second proportion of polyisocyanates;
a third proportion of a curative;
a fourth proportion of a soft polymer chain; and
a fifth proportion of a crosslinker;
exhibiting a tan delta curve characterized by:
a low-temperature tan delta between 0.05 and 0.25 at −20 degrees Celsius;
a high-temperature tan delta between 0.05 and 0.30 at 85 degrees Celsius; and
a maximum tan delta less than 0.4 at temperatures between −20 degrees Celsius and 85 degrees Celsius.

14. The polymer composition of claim 13:
exhibiting a storage modulus between 10 MPa and 1400 MPa at temperatures between −20 degrees Celsius and 85 degrees Celsius; and
exhibiting a room temperature storage modulus between 50 MPa and 400 MPa at 20 degrees Celsius.

15. The polymer composition of claim 13:
comprising a first amount of urethane linkages:
connecting the first proportion of polyol segments to a first subset of the second proportion of polyisocyanates; and
connecting the third proportion of the crosslinker to a second subset of the second proportion of polyisocyanates; and
comprising a second amount of urea linkages connecting the third proportion of the curative to a third subset of the second proportion of polyisocyanates.

16. The polymer composition of claim 13, exhibiting:
a haze value less than 1.3 percent;
a yellowness index less than 1.1; and
a surface roughness characterized by an arithmetic mean deviation between 5 nanometers and 40 nanometers.

17. The polymer composition of claim 16, exhibiting a temperature resistance characterized by:
a first haze ratio between negative twenty percent and twenty percent after 5 weeks of storage at −10 degrees Celsius;
a second haze ratio between negative twenty percent and twenty percent after 5 weeks of storage at 23 degrees Celsius; and
a third haze ratio between negative twenty percent and twenty percent after 5 weeks of storage at 50 degrees Celsius.

18. The polymer composition of claim 16, comprising a seventh quantity of a UV stabilizer configured to reduce environmentally-induced changes in yellowness index.

19. A polymer composition:
comprising a first amount of urethane linkages;
exhibiting:
a tan delta curve characterized by:
a low-temperature tan delta between 0.05 and 0.25 at −20 degrees Celsius;
a high-temperature tan delta between 0.05 and 0.30 at 85 degrees Celsius; and
a maximum tan delta less than 0.4 at temperatures between −20 degrees Celsius and 85 degrees Celsius;
a surface roughness characterized by an arithmetic mean deviation between 5 nanometers and 40 nanometers;
a haze value less than 1.3 percent; and
a yellowness index less than 1.1; and
wherein a film comprising the polymer composition exhibits a bend height less than 0.5 millimeters after subjecting the film to a bend test.

20. The polymer composition of claim 19, comprising:
a molar ratio of the first amount of urethane linkages to a second amount of urea linkages between two-to-five and six-to-five;
a first proportion of a polyisocyanate-terminated polyol;
a second proportion of an additional polyisocyanate;
a third proportion of a curative;
a fourth proportion of a soft polymer chain; and
a fifth proportion of a crosslinker.
